(19) United States
(12) Patent Application Publication
(10) Pub. No.: US 2023/0044345 A1
(43) Pub. Date: Feb. 9, 2023

(54) LAYOUT STRUCTURE OF FLEXIBLE CIRCUIT BOARD

(71) Applicant: CHIPBOND TECHNOLOGY CORPORATION, Hsinchu (TW)

(72) Inventors: Yu-Chen Ma, Kaohsiung City (TW); Pei-Wen Wang, Taichung City (TW); Hsin-Hao Huang, Kaohsiung City (TW); Gwo-Shyan Sheu, Kaohsiung City (TW)

(21) Appl. No.: 17/848,481

(22) Filed: Jun. 24, 2022

(30) Foreign Application Priority Data
Aug. 9, 2021 (TW) 110129353

(51) Int. Cl. H05K 1/18; H05K 1/02; H01L 23/498

(52) U.S. Cl. CPC H05K 1/189; H05K 1/0271; H01L 23/4985; H01L 23/49838; H01L 23/49811; H05K 2201/10674

(57) ABSTRACT

A layout structure of flexible circuit board includes a flexible substrate, a circuit layer, a flip-chip element and an anti-stress circuit layer. A chip mounting area and a circuit area are defined on a top surface of the flexible substrate. Bonding circuits and transmission circuits of the circuit layer are disposed on the chip mounting area and the circuit area respectively. The flip-chip element is disposed on the chip mounting area and includes bumps and a chip having a long side margin and conductive pads, the bumps are provided to connect the conductive pads and the bonding circuits. Anti-stress circuits of the anti-stress circuit layer are disposed on the chip mounting area and parallel to the long side margin of the chip, and the bumps are located between the anti-stress circuits and the long side margin of the chip.

### FIELD OF THE INVENTION

This invention relates to a flexible circuit board, and more particularly to a layout structure of a flexible circuit board.

### BACKGROUND OF THE INVENTION

Flexible circuit board, which is small in size, bendable and thin, is widely used in mobile devices, such as smartphones, laptops and smartwatches. The current mobile devices are becoming more and more light and thin, the thickness and overall dimension of the flexible circuit board have to be reduced, but that means it is more difficult to manufacture the flexible circuit board. Conventionally, in flip-chip bonding process, a chip is aligned with a flexible substrate, and bumps on the chip are eutectic bonded to circuit layer on the flexible substrate by heating and pressure contacting. As a result, the bumps on the chip may generate stress on the flexible substrate during flip-chip bonding to pull a circuit layer and break circuits.

### SUMMARY

One object of the present invention is to provide anti-stress circuits to strengthen the area on a flexible substrate where is connected to bumps so as to protect bonding circuits on the area from breaking caused by stress generated during flip-chip bonding.

A layout structure of flexible circuit board includes a flexible substrate, a circuit layer, a flip-chip element and an anti-stress circuit layer. A chip mounting area and a circuit area are defined on a top surface of the flexible substrate. The circuit layer includes a plurality of bonding circuits and transmission circuits which are connected to each other and located on the chip mounting area and the circuit area, respectively. The flip-chip element is disposed on the chip mounting area and includes a chip and a plurality of bumps, the chip includes a long side margin and a plurality of conductive pads, the bumps are provided to connect the conductive pads of the chip and the bonding circuits. The anti-stress circuit layer includes a plurality of anti-stress circuits which are disposed on the chip mounting area and parallel to the long side margin of the chip. The bumps are located between the anti-stress circuits and the long side margin of the chip.

The anti-stress circuits of the present invention are parallel to the long side margin of the chip and used to reduce the stress acting on the flexible substrate and generated by the bumps during flip-chip bonding, thus the bonding circuits of the circuit layer are protected from breaking.

### DESCRIPTION OF THE DRAWINGS

FIG. 1 is a top view diagram illustrating a layout structure of flexible circuit board in accordance with one embodiment of the present invention.

FIG. 2 is a cross-section view diagram illustrating a layout structure of flexible circuit board in accordance with one embodiment of the present invention.

FIG. 3 is an enlarged partial diagram illustrating a layout structure of flexible circuit board in accordance with one embodiment of the present invention.

### DETAILED DESCRIPTION OF THE INVENTION

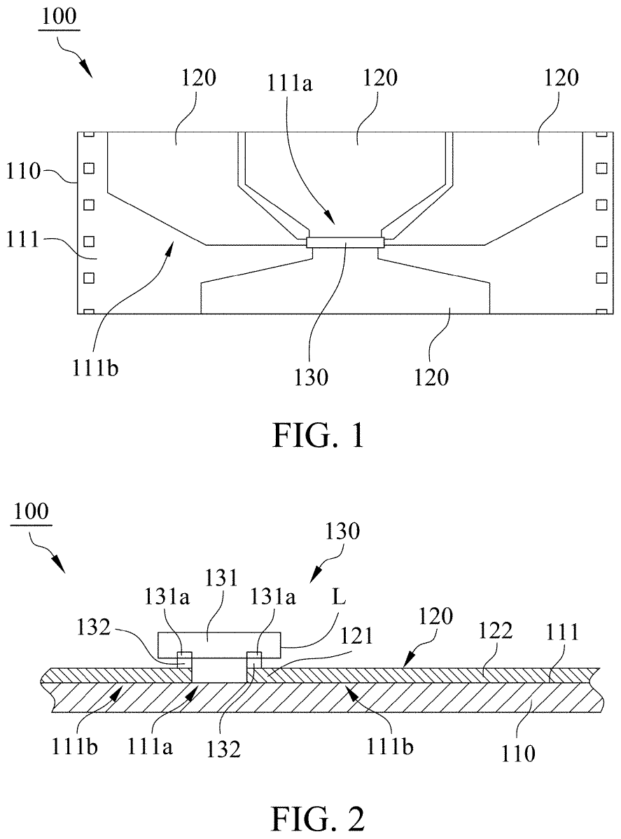

With reference to FIGS. 1 and 2, a layout structure of flexible circuit board 100 in accordance with one embodiment of the present invention includes a flexible substrate 110, a circuit layer 120 and a flip-chip element 130. The flexible substrate 110 is made of polymer material having high degree of electric insulation, stability and chemical resistance, like polyimide. The circuit layer 120 is a patterned copper layer which is plated or laminated onto the flexible substrate 110. The flip-chip element 130 is mounted on the flexible substrate 110 and electrically connected to the circuit layer 120 for electric signal transmission.

With reference to FIGS. 1 and 2, a chip mounting area 111a and a circuit area 111b are defined on a top surface 111 of the flexible substrate 110. The circuit layer 120 includes a plurality of bonding circuits 121 and transmission circuits 122 which are connected to each other, the bonding circuits 121 are located on the chip mounting area 111a, and the transmission circuits 122 are located on the circuit area 111b. Preferably, the bonding circuits 121 and the transmission circuits 122 are plated with a tin layer for the connection of the bonding circuits 121 to the flip-chip element 130 and the connection of the transmission circuits 122 to other electronic device. The circuit layer 120 is coated with a solder resist (not shown), except where the circuit layer 120 is connect to the flip-chip element 130 and electronic device, thereby protecting the circuit layer 120 from heat damage.

The flip-chip element 130 is disposed on the chip mounting area 111a defined on the top surface 111 of the flexible substrate 110, and it includes a chip 131 and a plurality of bumps 132. The chip 131 has a long side margin L and a plurality of conductive pads 131a, each of the bumps 132 is provided to connect one of the conductive pads 131a of the chip 131 to one of the bonding circuits 121 of the circuit layer 120. The bumps 132 can be formed on the chip 131 in advance by well known method in the art using gold, copper, nickel, or other metallic or alloy materials.

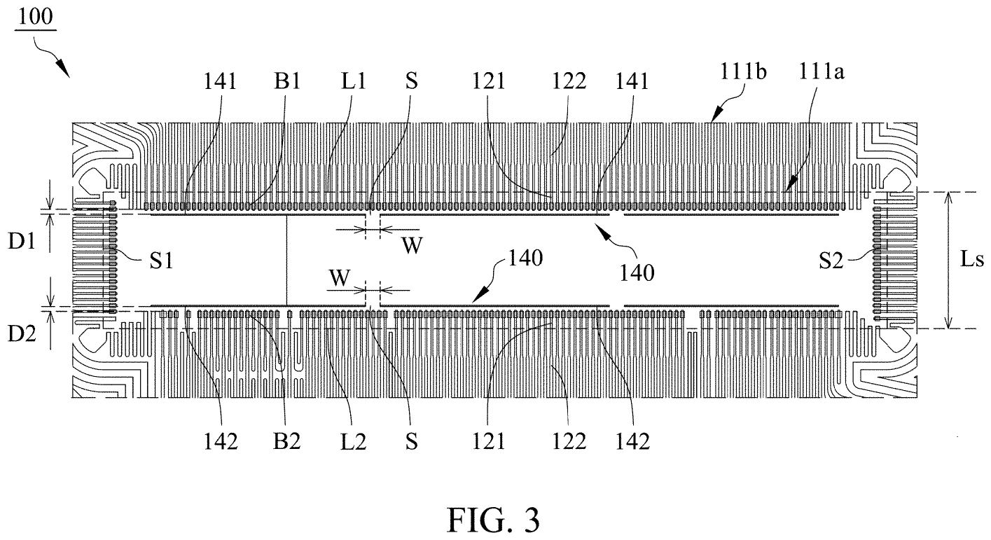

FIG. 3 is an enlarger partial diagram showing the layout structure of flexible circuit board 100. In this embodiment, the flip-chip element 130 includes a plurality of first bumps B1 and second bumps B2, the chip 131 has a first long side margin L1, a second long side margin L2 and two short side margins S1 and S2 which define a rectangular area corresponding to the chip mounting area 111a, the other area outside of the rectangular area is corresponding to the circuit area 111b. The second bumps B1 are close to the first long side margin L1, and the second bumps B2 are close to the second long side margin L2. Some of the bonding circuits 121 are electrically connected to the first bumps B1, and some of the bonding circuits 121 are electrically connected to the second bumps B2.

Preferably, the layout structure of flexible circuit board 100 further includes an anti-stress circuit layer 140. The anti-stress circuit layer 140 includes a plurality of first anti-stress circuits 141 and second anti-stress circuits 142 which are both located on the chip mounting area 111a. The first anti-stress circuits 141 are located adjacent to the first long side margin L1 and aligned in a line parallel to the first long side margin L1, thus the first anti-stress circuits 141 are also parallel to the first long side margin L1. The first bumps B1 of the flip-chip element 130 are located between the first anti-stress circuits 141 and the first long side margin L1, and the first anti-stress circuits 141 are provided to reduce stress, which is acting on the flexible substrate 110 and generated by the first bumps B1, during flip-chip bonding, thus the bonding circuits 121 connected to the first bumps B1 are protected from breaking. The second anti-stress circuits 142 are located adjacent to the second long side margin L2 and aligned in a line parallel to the second long side margin L2, in other words, the second anti-stress circuits 142 are parallel to the second long side margin L2. The second bumps B2 of the flip-chip element 130 are located between the second anti-stress circuits 142 and the second long side margin L2. The second anti-stress circuits 142 can reduce stress, which is acting on the flexible substrate 110 and generated by the second bumps B2 during flip-chip bonding. As a result, the bonding circuits 121 connected to the second bumps B2 are protected from breaking.

In this embodiment, stress generated during flip-chip bonding may damage the bonding circuits 121 due to there are no bumps or circuits between the first anti-stress circuits 141 and the second anti-stress circuits 142, for this reason, the first anti-stress circuits 141 and the second anti-stress circuits 142 have to be arranged adjacent to the first bumps B1 and the second bumps B2 respectively to reduce the stress acting on the bonding circuits 121.

Preferably, in order to prevent the anti-stress circuit layer 140 from obstructing the flow of underfill of the chip 131, a space S having a width W greater than 50 um is provided between the adjacent first anti-stress circuits 141 and between the adjacent second anti-stress circuits 142. Thus, the underfill can flow between the chip 131 and the flexible substrate 110 via the space S.

With reference to FIGS. 2 and 3, in this embodiment, the short side margins S1 and S2 of the chip 131 have a length Ls greater than 1.5 mm, and the first bumps B1 and the second bumps B2 of the flip-chip element 130 have a height less than 15 um, pressure marks may occur on the chip 131 due to the press of the anti-stress circuit layer 140 during flip-chip bonding. Consequently and preferably, a first distance D1 between each of the first anti-stress circuits 141 and a corresponding one of the first bumps B1 is designed to be smaller than 50 um, and a second distance D2 between each of the second anti-stress circuits 142 and a corresponding one of the second bumps B2 is designed to be smaller than 50 um. The chip 131 is protected from the contacting of the anti-stress circuit layer 140 by the supporting of the first bumps B1 and the second bumps B2.

In the present invention, the anti-stress circuits parallel to the long side margin L of the chip 131 are provided to reduce the stress which is generated by the bumps 132 of the flip-chip element 130 and acting on the flexible substrate 110 during flip-chip bonding so as to prevent the bonding circuits 121 of the circuit layer 120 from breaking.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

What is claimed is:

1. A layout structure of flexible circuit board comprising:
a flexible substrate including a top surface, a chip mounting area and a circuit area are defined on the top surface;
a circuit layer including a plurality of bonding circuits and a plurality of transmission circuits, the plurality of bonding circuits are disposed on the chip mounting area, the plurality of transmission circuits are disposed on the circuit area, each of the plurality of bonding circuits is connected to a corresponding one of the plurality of transmission circuits;
a flip-chip element disposed on the chip mounting area and including a chip and a plurality of bumps, the chip includes a long side margin and a plurality of conductive pads, each of the plurality of bumps is configured to connect a corresponding one of the plurality of conductive pads of the chip to a corresponding one of the plurality of bonding circuits; and
an anti-stress circuit layer including a plurality of anti-stress circuits, the plurality of anti-stress circuits are disposed on the chip mounting area and parallel to the long side margin of the chip, and the plurality of bumps are located between the plurality of anti-stress circuits and the long side margin of the chip.

2. The layout structure of flexible circuit board in accordance with claim 1, wherein a first distance less than 50 um is provided between each of the plurality of anti-stress circuits and a corresponding one of the plurality of bumps.

3. The layout structure of flexible circuit board in accordance with claim 1, wherein the plurality of anti-stress circuits are aligned in a line parallel to the long side margin of the chip.

4. The layout structure of flexible circuit board in accordance with claim 1, wherein a space is located between adjacent of the plurality of anti-stress circuits and has a width greater than 50 um.

5. The layout structure of flexible circuit board in accordance with claim 2, wherein a space is located between adjacent of the plurality of anti-stress circuits and has a width greater than 50 um.

6. The layout structure of flexible circuit board in accordance with claim 3, wherein a space is located between adjacent of the plurality of anti-stress circuits and has a width greater than 50 um.

7. The layout structure of flexible circuit board in accordance with claim 1, wherein a short side margin of the chip has a length greater than 1.5 mm.

8. The layout structure of flexible circuit board in accordance with claim 1, wherein the plurality of bumps of the flip-chip element have a height less than 15 um.

9. The layout structure of flexible circuit board in accordance with claim 1, wherein the flip-chip element includes a plurality of first bumps and a plurality of second bumps, the chip has a first long side margin and a second long side margin, the plurality of first bumps are adjacent to the first long side margin, and the plurality of second bumps are adjacent to the second long side margin.

10. The layout structure of flexible circuit board in accordance with claim 9, wherein the anti-stress circuit layer includes a plurality of first anti-stress circuits and a plurality of second anti-stress circuits, a first distance less than 50 um is provided between each of the plurality of first anti-stress circuits and a corresponding one of the plurality of first bumps, a second distance less than 50 um is provided between each of the plurality of second anti-stress circuits and a corresponding one of the plurality of second bumps, and there are no bumps or circuits between the plurality of first anti-stress circuits and the plurality of second anti-stress circuits.

11. The layout structure of flexible circuit board in accordance with claim 10, wherein the chip has two short side margins each having a length greater than 1.5 mm, the plurality of first bumps and the plurality of second bumps of the flip-chip element have a height less than 15 um.
